(19) United States
(12) Patent Application Publication
(10) Pub. No.: US 2018/0241375 A1
(43) Pub. Date: Aug. 23, 2018

(54) VARIABLE ATTENUATOR

(71) Applicant: SUMITOMO ELECTRIC DEVICE INNOVATIONS, INC., Yokohama-shi (JP)

(72) Inventors: Akio Oya, Yokohama-shi (JP); Makoto Kondo, Yokohama-shi (JP)

(21) Appl. No.: 15/903,220

(22) Filed: Feb. 23, 2018

(30) Foreign Application Priority Data
Feb. 23, 2017 (JP) 2017-032039
Aug. 16, 2017 (JP) 2017-157186

(51) Int. Cl. H03H 11/24; H01P 1/22; H03H 7/25

(52) U.S. Cl. CPC H03H 11/245; H03G 1/0052; H03H 7/253; H01P 1/22

(57) ABSTRACT

A variable attenuator (v-ATT) is disclosed. The v-ATT includes an input terminal, an output terminal, a transmission line between the input and output terminals, at least two stages provided between the transmission line and the ground, and a bias unit. Each of the stages includes a field effect transistor (FET) that varies impedance between the transmission line and the ground according to a bias provided to the gate thereof. The bias unit generates the biases each provided to the stages. One of the features of the v-ATT is that at least one of the stages receives at least one of the biases that is different from biases provided to other of the at least one of the stages.

### BACKGROUND OF INVENTION

### 1. Field of Invention

The present invention relates to a variable attenuator, in particular, relates to an attenuator for signal containing high frequency components and the attenuation thereof may be varied by a control signal.

### 2. Related Background Arts

A variable attenuator whose attenuation may be controlled by a control signal has been known in the field as a voltage variable attenuator (v-ATT). Japanese Patent Applications laid open No. JP-2000-124709A and JP-2009-200671A have disclosed such v-ATTs. However, such a conventional v-ATT has shown response that a signal passing therethrough is distorted or increases higher order harmonics of the signal when a range of the attenuation is widened; that is, a conventional v-ATT has a subject that the range of the attenuation becomes a trade-off with respect to the signal distortion.

### SUMMARY OF INVENTION

An aspect of the present invention relates to a variable attenuator (v-ATT) that includes an input terminal, an output terminal, a transmission line, first and second stages, and a bias unit. The input terminal receives a signal to be attenuated. The output terminal outputs an attenuated signal derived from the signal entering at the input terminal. The transmission line connects the input terminal with the output terminal and carries the attenuated signal thereon. The first and second stages are provided between the transmission line and he ground, each include a field effect transistor (FET) having a gate and two current terminals connected with the transmission line and the ground, respectively. The FET varies impedance between the two current terminals according to a bias supplied to the gate thereof. The bias unit includes an input and generates biases supplied to the first and second FETs in the first and second stages according to a control signal provided to the input of the bias unit. The bias unit supplies thus generated biases to the first and second stages. A feature of the present invention is that the biases supplied to the first and second stages are different from and independent each other.

### BRIEF DESCRIPTION OF THE DRAWINGS

The invention will now be described by way of example only with reference to the accompanying drawings in which:

FIG. 1 shows a circuit diagram of a variable attenuator (v-ATT) according to the first embodiment of the present invention;

FIG. 2A and FIG. 2B compare variations of a drain current ΔId and magnitudes of the third order intercept point (IIP3) against the control signal of the variable attenuator of the present invention (FIG. 2B) with those of a conventional v-ATT;

FIG. 3A and FIG. 3B compare the attenuation of the conventional v-ATT shown in FIG. 11A with that of the v-ATT of the first embodiment of the present invention in FIG. 11B;

FIG. 4 shows a circuit diagram of another v-ATT according to the second embodiment of the present invention;

FIG. 5A and FIG. 5B compare the distortion performance measured through the IIP3 and the attenuation of the v-ATT according to the second embodiment of the present invention with those of the conventional v-ATT shown in FIG. 11B;

FIG. 6 shows a functional block diagram of an electronic apparatus according to the third embodiment of the present invention;

FIG. 7A shows a circuit diagrams of a v-ATT modified from the v-ATT of the first embodiment shown in FIG. 1, and FIG. 7B shows a circuit diagram of another v-ATT according to the fourth embodiment of the present invention;

FIG. 8A and FIG. 8B show the gate biases and the attenuation, respectively, of the v-ATT that is modified from the v-ATT of the first embodiment;

FIG. 9A and FIG. 9B show the gate biases for the FETs and the attenuation performance, respectively, of the v-ATT against the control signal according to the fourth embodiment of the present invention;

FIG. 10 shows a circuit diagram of a v-ATT modified from the v-ATT of the fourth embodiment shown in FIG. 8B;

FIG. 11A and FIG. 11B show circuit diagrams of conventional v-ATTs;

FIG. 12A and FIG. 12B show distortion performance measured through the IIP3 and the attenuation performance against the control signal of the conventional v-ATTs shown in FIG. 11A and FIG. 11B; and

FIG. 13 shows a variation of a drain current against a variation of the control signal in the conventional v-ATT shown in FIG. 11A.

### DESCRIPTION OF EMBODIMENT

Next, embodiments according to the present invention will be described as referring to accompanying drawings. In the description of the drawings, numerals or symbols same with or similar to each other will refer to elements same with or similar to each other without duplicated explanations. The present invention is not restricted to those embodiments, but defined in claims presented below and intended to cover all changes and modifications thereof and equivalents thereto.

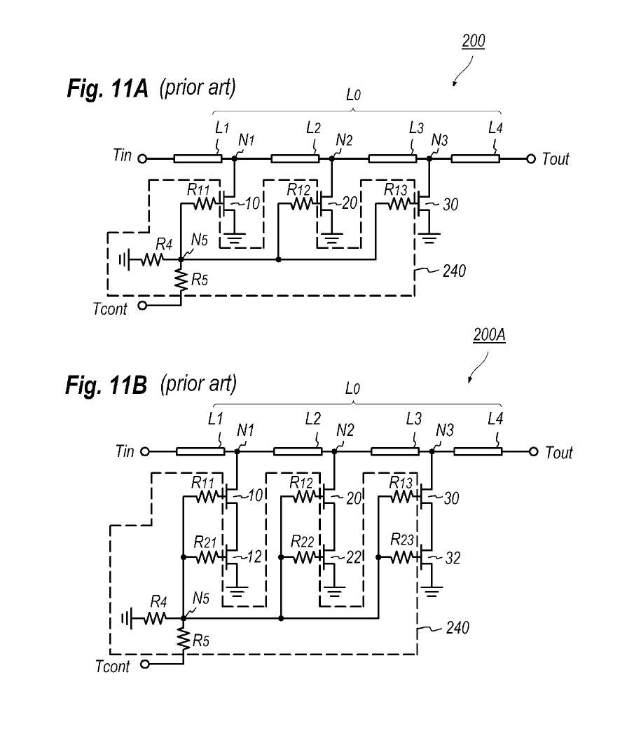

Some examples comparable to the present invention will be first described. FIG. 11A shows a circuit diagram of a variable attenuator (v-ATT) comparable to a v-ATT of the present invention. The v-ATT 200 shown in FIG. 11A includes an input terminal Tin, an output terminal Tout, a transmission line L₀, three field effect transistors (FETs), 10 to 30, and a bias unit 40. The transmission line L₀, which connects the input terminal Tin with the output terminal Tout, is divided into four transmission line elements, L₁ to L₄, between which three nodes, N₁ to N₃, are provided. Some conventional circuits provide coupling capacitors between the input terminal Tin and the first transmission line element L₁ and between the fourth transmission line element L₄ and the output terminal Tout. The FETs, 10 to 30, in one of current terminals thereof are connected between the nodes, N₁ to N₃, and the ground. That is, the FETs, 10 to 30, couple the intermediate nodes, N₁ to N₃, of the transmission line L₀ with the ground.

The bias unit 40, which determines gate biases to the respective FETs, 10 to 30, provides resistors, R₁₁ to R₁₃, R₄ and R₅. Former three resistors, R₁₁ to R₁₃, are put between the common node N₅ and respective gates of the FETs, 10 to 30, where the common node N₅ is formed by dividing the control signal supplied to the control terminal Tcont by two resistors, R₅ and R₄. The control signal Tcont is supplied to the respective gate of the FETs, 10 to 30, divided by two resistors, R₅ and R₄.

The signal entering the input terminal Tin is carried on the transmission line L₀ and appears in the output terminal Tout after a portion thereof is split by the FETs, 10 to 30, when the FETs, 10 to 30, turn on and reduce impedance between the current terminals thereof. Thus, the FETs, 10 to 30, may attenuate the signal. When the control signal Vcont is low enough for the level of the node N₅ to be deeper than the pinch-off voltage of the FETs, 10 to 30; the FETs, 10 to 30, turn off and substantially no portion of the signal carried on the transmission line L₀ is split to the ground through the FETs, 10 to 30, and the signal entering the input terminal Tin appears in the output terminal Tout accompanying with substantially no attenuation.

FIG. 11B shows another circuit diagram of a v-ATT 200A that is also comparable with the present invention. The v-ATT 200A has a feature distinguishable from the v-ATT 200 shown in FIG. 11A that the v-ATT 200A provides other FETs, 12 to 32, connected in series with the FETs, 10 to 30. That is, the transmission line Lo in the intermediate nodes, N₁ to N₃, thereof are grounded through FETs, 10 to 30, and 12, to 32, each connected in series. The FETs, 12 to 32, in the gates thereof are coupled with the common node N₅ through resistors, R₂₁ to R₂₃.

Two conventional v-ATTs, 200 and 200A, are evaluated in attenuation and the third order intercept point (IIP3) thereof. In the evaluation, FETs, 10 to 30 and 12 to 32, are assumed to be a type of high electron mobility transistor (HEMT) configured with a carrier transporting layer, which is often called as a channel layer, made of InGaAs; a carrier supplying layer, which is sometimes called as a barrier layer made of AlGaAs; a gate length of 0.1 μm; and a gate width of 100 μm. The signal entering the input terminal Tin has a frequency of 20 GHz with power of 0 dBm. The IIP3 is evaluated by superposing another signal on the primary signal described above, where another signal has a frequency apart by 10 MHz from that of the primary signal. The control signal Vcont varies from −3 to 0 V, where the control signal Vcont of −3 V fully turns off the FETs, 10 to 30, while, the control signal Vcont of 0 V substantially turns on the FETs, 10 to 30. The resistors, R₁₁ to R₁₃ and R₂₁ to R₂₃, have resistance of 1 kΩ and other resistors, R₄ and R₅, have resistance of 2 kΩ and 6 kΩ that is, the resistive divider formed by the resistors, R₄ and R₅, convers the control signal Vcont into a quarter thereof.

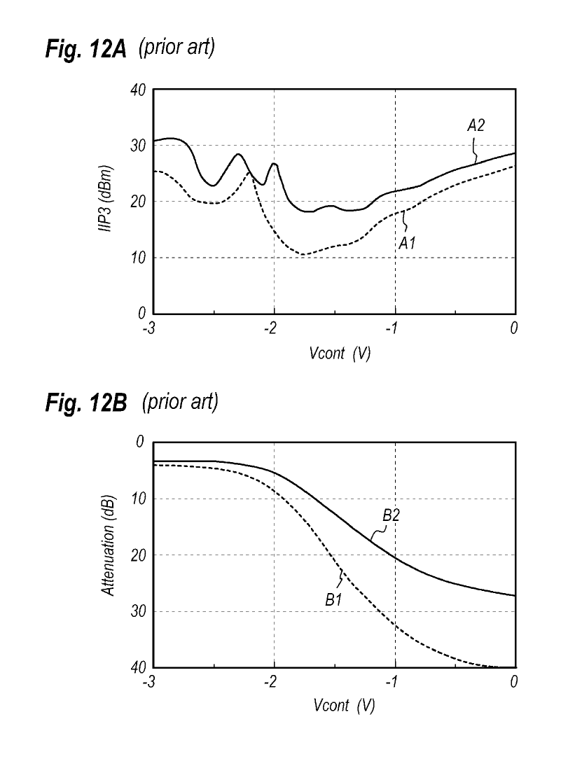

FIG. 12A and FIG. 12B show behaviors of the IIP3 and the attenuation against the control signal Vcont in the v-ATTs, 200 and 200A, where the IIP3 corresponds to the input power when the third order component in magnitude thereof becomes equal to that of the fundamental component, while, the attenuation corresponds to a ratio of the signal appearing in the output terminal Tout against that in the input terminal Tin. The attenuation of 0 dB means that no signal loss is caused by the v-ATT.

Referring to FIG. 12A, the v-ATT 200 shows a smaller IIP3, in particular, the IIP3 decreases to form a hollow in the range of the control signal Vcont from −2 to −1 V, where the hollow has a bottom level of around merely 10 dBm. While, the v-ATT 200A improves the IIP3 compared with that of the v-ATT 200 by about 10 dB in the range of the control signal Vcont from −2 to −1.5 V. Referring to FIG. 12B, the v-ATT 200 shows the residual attenuation of 4 dB at the control signal of −3 V, which makes the FETs, 10 to 30, to turn off; but the attenuation reaches 40 dB at the control signal Vcont of 0 V, that is, the v-ATT 200 secures the attenuation width of about 36 dB. For the v-ATT 200A, although the residual attenuation becomes about 4 dB at the control signal Vcont of −3 V, which is comparable with that of the v-ATT 20, the attenuation shows merely 26 dB at the control signal Vcont of 0 V, which means that the attenuation range of the v-ATT 200A becomes only 22 dB. Thus, the v-ATT 200A that provides the cascade configuration for the FETs, 10 to 30, may improve the distortion performance measured through the IIP3, but the attenuation at the control signal Vcont of 0 V becomes insufficient. Thus, the conventional v-ATT 200A makes the distortion performance inconsistent with the attenuation performance.

This inconsistency between the distortion performance and the attenuation performance in a conventional v-ATT seems to closely relate to a variation in the drain current against a variation of the control signal, namely, |ΔId|/|ΔVcont|, which has a dimension of the conductance. The transmission line L₀ only carries the signal with high frequency components but substantially cuts a DC or low frequency components. Accordingly, the index |ΔId|/|ΔVcont| corresponds to the trans-conductance of the FETs, 10 to 30, at no drain bias.

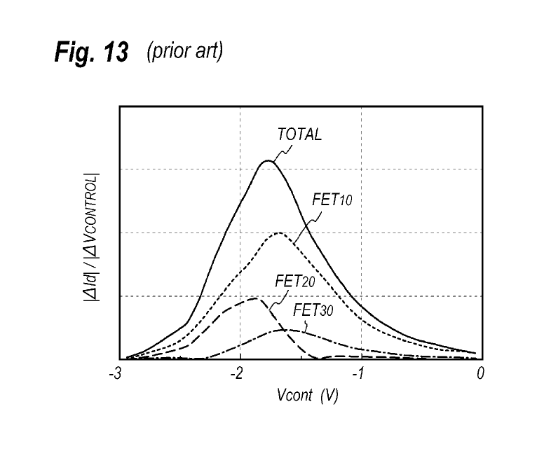

FIG. 13 shows the trans-conductance of respective FETs, 10 to 30 against the control signal Vcont, that is, variations of the drain current flowing from the nodes, N₁ to N₃, to the ground through the respective FETs, 10 to 30, against the variation of the control signal Vcont. FIG. 13 also shows a total trans-conductance that sums the respective trans-conductance of the FETs, 10 to 30. As shown in FIG. 13, the FET 10 that is arranged closest to the input terminal Tin shows the trans-conductance greater than those of the other FETs, 20 and 30, which means that the signal split to the ground through the FET 10 becomes greater than those split through the FETs, 20 and 30. Also, the trans-conductance |ΔId|/|ΔVcont| for the respective FETs, 10 to 30, become maxima at the control signal Vcont of about −1.7 V common to the FETs, 10 to 30.

A large trans-conductance |ΔId|/|ΔVcont| means that the drain impedance viewing the FETs, 10 to 30, from the transmission line L₀ widely vary as the variation of the control signal Vcont, which deviates the impedance of the transmission lint L₀ and degrades, or increases the distortion of the signal carried on the transmission line L₀. The distortion performance of the v-ATT degrades at the control signal Vcont widely varies the trans-conductance of the FETs, 10 to 30.

The cascade connection may suppress the variation of the drain impedance of the FETs, 10 to 30, provided in respective high sides of the cascade connection, namely, those arranged closed to the transmission line L₀. Accordingly, the v-ATT 200A with the cascade connection may improve the distortion performance thereof compared with the arrangement of the v-ATT 200 with no cascade connection. However, the cascade connection inevitably leaves substantial resistance between the current terminals of a FET; accordingly, the attenuation of the v-ATT 200A becomes degraded when the control signal turns on the FET, that is, the control signal Vcont becomes 0 V.

### First Embodiment

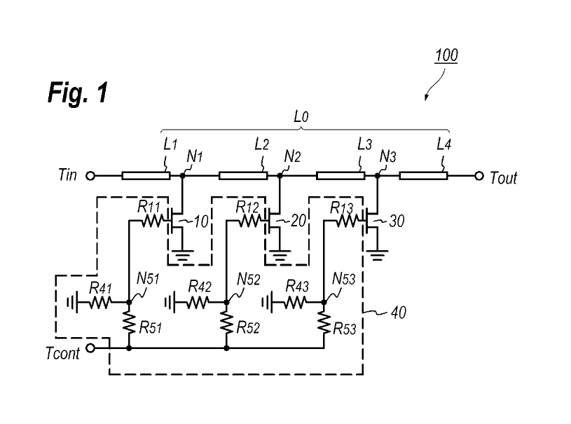

Next, a variable attenuator (v-ATT) according to the first embodiment of the present invention will be described. FIG. 1 shows a circuit diagram of the v-ATT 100 according to the first embodiment of the present invention. The v-ATT 100 includes, same with those implemented within the conventional v-ATTs, 200 and 200A, an input terminal Tin, an output Terminal Tout, transmission line L₀ provided between the input terminal Tin and the output terminal Tout, three field effect transistors (FETs), 10 to 30, and a bias unit 40. Although the v-ATT 100 directly connects the transmission line L₀ with the input terminal Tin and with the output terminal Tout, the transmission line L₀ may be indirectly connected with those terminals, Tin and Tout, through capacitors that cut a DC component and low frequency components contained in a signal entering the input terminal Tin and to be attenuated.

The transmission line L₀ includes four transmission line elements, L₁ to L₄, which interpose nodes, N₁ to N₃, therebetween. The FETs, 10 to 30, are connected between the nodes, N₁ to N₃, and the ground. Specifically, respective two current terminals of the FETs, 10 to 30, namely, drains and sources, are connected between the nodes, N₁ to N₃, and the ground, while, the respective control terminal, namely gates, are connected to the bias unit 40.

The bias unit 40 includes three blocks each including three resistors that constitute a T-network. Specifically, resistors, R₁₁, R₄₁, and R₅₁ constitute the first T-network between the input Tcont of the bias unit 40 and the gate of the first FET 10. Resistors, R₁₂, R₄₁, and R₅₂ constitute the second T-network between the input Tcont and the gate of the second FET 20; and last three resistors, R₁₃, R₄₃, and R₅₃ constitute the third T-network between the input Tcont and the gate of the third FET 30. Thus, the bias unit 40 has the input Tcont common to the three T-networks. Also, the first T-network and the first FET 10 constitute the first stage, the second T-network and the second FET 20 constitute the second stage, and the third T-network and the third FET 30 constitute the third stage, with respect to the transmission line L₀.

The signal entering the input terminal Tin is carried on the transmission line L₀. Increasing the control signal Vcont supplied to the input Tcont, which makes equivalent resistance between the current terminals of the respective FETs, 10 to 30, small; the signal carried on the transmission line Lo is partly split to the ground through the FETs, 10 to 30, and the magnitude of the signal appearing in the output terminal Tout attenuates. Oppositely, decreasing the control signal Vcont such that the gate biases of the respective FETs, 10 to 30, becomes deeper than pinch-off voltages of the FETs, 10 to 30; the FETs, 10 to 30, turn off and the high frequency signal entering the input terminal Tin appears in the output terminal Tout without being split to the ground through the FETs, 10 to 30.

A feature of the v-ATT 100 shown in FIG. 1 is that the FETs, 10 to 30, are biased in the gates thereof by the unique control signal Vcont but through the respective T-networks each including resistive divider constituted by respect two resistors, R₄₁ and R₅₁, R₄₂ and R₅₂, and R₄₃ and R₅₃, respectively. Specifically the first FET 10 in the gate thereof is biased by the control signal Vcont divided by the first resistive divider including the resistors, R₅₁ and R₄₁, the second FET 20 is biased also by the control signal Vcont divided by the second resistive divider including the resistors, R₄₂ and T₅₂; and the third FET 30 is biased also by the control signal Vcont divided by the third resistive divider including the resistors, R₄₃ and R₅₃. Accordingly, differentiating the dividing ratios of the respective resistive divider in the T-networks, the biases supplied to the gates of the FETs, 10 to 30, may be optionally varied.

The v-ATT 100 shown in FIG. 1 is compared with the conventional v-ATT 200 shown in FIG. 11A also having three FETs that are biased with a unique gate bias common to each other. Specifically, the FETs, 10 to 30, in the conventional v-ATT 200 receives the gate biases derived from the control signal Vcont divided only by the resistive divider including the resistors, R₅ and R₄, whose resistance were 2 kΩ and 6 Ω respectively. The v-ATT 100 of the first embodiment has the first resistive divider of the resistors, R₅₁ and R₄₁, whose resistance is common to the resistance of the resistors, R₅ and R₄, of the conventional v-ATT 200 described above. While, other resistors, R₄₂ to R₅₃, are set in the resistance thereof to be 4 kΩ. That is, in the v-ATT 100 of the first embodiment, the first FET 10 receives a quarter while the second and third FETs, 20 and 30, receive a half of the control signal Vcont; accordingly, the gate bias for the first FET 10 varies from −0.75 to 0 V, while, the second and the third FETs, 20 and 30, varies in the gate bias thereof from −1.5 to 0 V as the control signal Vcont varies from −3 to 0 V.

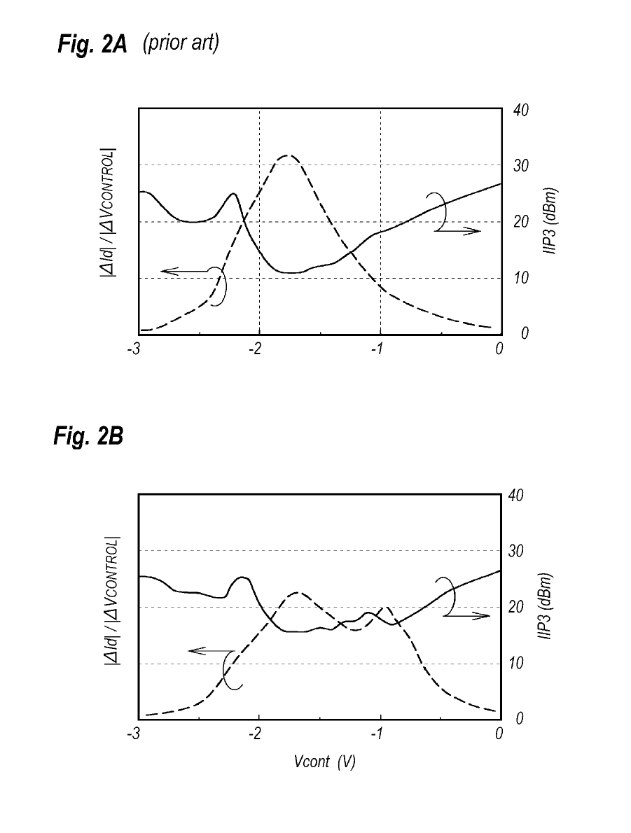

FIG. 2A and FIG. 2B compare the conductance |ΔId|/|ΔVcont| and the distortion performance measured through the IIP3 of the v-ATT 100 of the first embodiment with the v-ATT 200 of the conventional one, where the conductance |ΔId|/|ΔVcont| is a total conductance summing respective conductance of the FETs, 10 to 30. As already described, referring to FIG. 2A, the conductance shows a sharp peak at the control signal Vcont of −1.7 V; while, the distortion performance measured through the IIP3 causes a valley for the control signal Vcont between −2 to −1 V.

On the other hand, the conductance |ΔId|/|ΔVcont| of the v-ATT 100 of the embodiment makes the peak relatively dull. This is because the FET 10 and rest two FETs, 20 and 30, are biased in the gates thereof independently, exactly, scan ranges in the gate biases for the FETs, 10 to 30, are different each other. That is, the position of the peak in the conductance for the first FET 10 appears at a control signal that is different from the control signal by which the FETs, 20 and 30, show respective maxima. Accordingly, the control signal Vcont from −2 V to −1 V may improve the distortion performance measured through the IIP3 by about 5 dB from that of the conventional v-ATT 200.

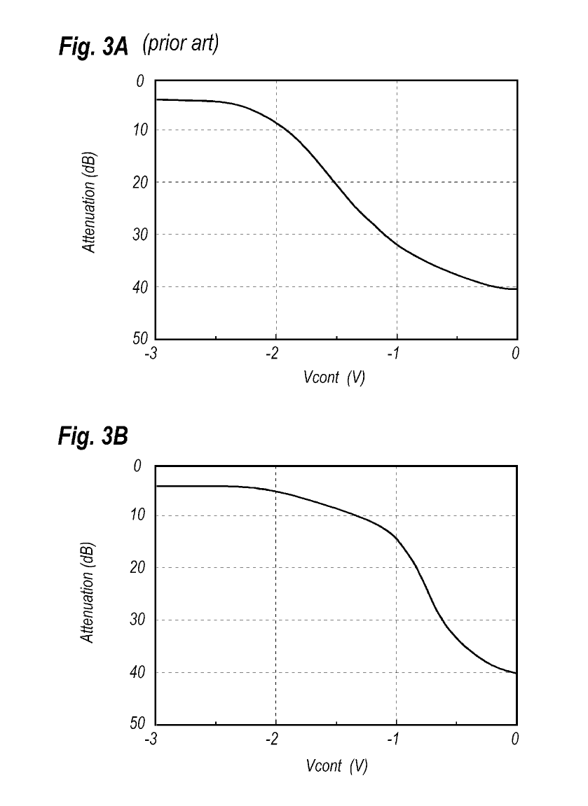

FIG. 3A and FIG. 3B compare the attenuation of the conventional v-ATT 200 shown in FIG. 11A with that by the v-ATT 100 of the first embodiment. The attenuation of the v-ATTs, 100 and 200, becomes substantially comparable at a value of about 4 dB for the control signal Vcont of −3 V, which fully turns off the FETs, 10 to 30; and the attenuation for the control signal Vcont of 0 V reaches 40 dB, which is also comparable to each other.

The v-ATT 100 of the first embodiment differs the gate bias supplied to at least one of the FETs from those supplied to the rest FETs. That is, the first FET 10 receives the gate bias different from those supplied to the rest FETs, 20 and 30. This arrangement of the gate biases may shift the peak in the conductance of the first FET from the peaks attributed to the rest FETs; accordingly, the sharpness in the peak of the conductance of the FETs, 10 to 30, may be dulled and the distortion performance reflected in the IIP3 is improved.

The gate bias supplied to the first FET 10, specifically from −0.75 to 0 V with the center of −0.375 V, is different from the gate bias supplied to the second and the third FETs, 20 and 30, specifically, from −1.5 to 0 V with a center of −0.75V. This arrangement of the gate biases may improve the distortion performance measured through the IIP3 without narrowing the attenuation range. Although the first embodiment of the v-ATT 100 shifts the gate bias for the first FET 10 and other two FETs, 20 and 30, receive the gate biases same with each other. However, the combination of which FET receives a gate bias different from the other gate biases is not restricted to that of the first embodiment. Also, the embodiment sets the gate bias in the range thereof for the first FET 10 is set to be narrower than those for the other FETs, 20 and 30; the range of the gate bias for the first FET 10 may be widened compared with those for the other FETs, 20 and 30. Further, the embodiment sets the center of the range of the gate bias for the first FET 10 higher than those for the other two FETs, 20 and 30; but the center of the range of the gate bias for the first FET 10 may be lower than those for the other two FETs, 20 and 30.

Referring to FIG. 13, the conductance of the FET 10 shows the largest peak, specifically, the peak in the conductance of the first FET 10 becomes substantially sum of the peaks for the second and third FETs, 20 and 30. Then, the gate bias for the first FET 10 is set to be different from those for the second and third FETs, 20 and 30. Thus, the peak appearing in the total conductance of the v-ATT 100 may be dulled to improve the distortion performance measured through the IIP3.

### Second Embodiment

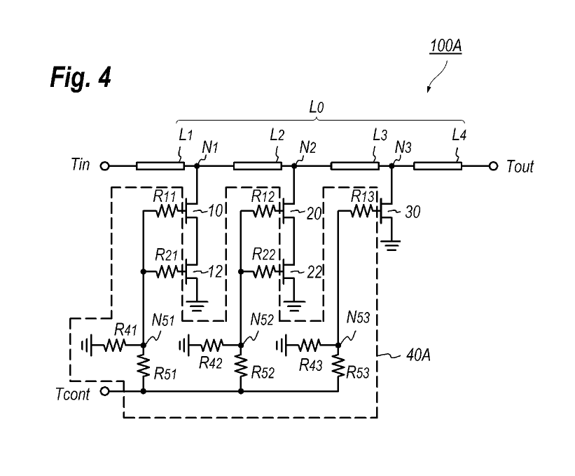

FIG. 4 shows a circuit diagram of another v-ATT according to the second embodiment of the present invention. The v-ATT 100A shown in FIG. 4 has a feature that FETs connected between the transmission line L₀ and the ground have cascade connections. That is, two FETs, 10 and 12, with the cascade connection are provided between the intermediate node N₁ and the ground. Two FETs, 20 and 22, also with the cascade connection are provided between the second intermediate node N₂ and the ground. However, the FET 30 in the third stage, namely, the stage provided closest to the output terminal Tout, has the normal connection; that is no additional FET is connected in series with the third FET 30. The cascade connection of the FETs in the first and second stages means that one of the current nodes, the source, of the high side FET is directly connected with another of the current nodes, the drain, of the low side FET.

The distortion performance measured through the IIP3 and the attenuation of the v-ATT 100A of the second embodiment are evaluated. Parameters set in the evaluation are, resistance of the resistors, R₄₁ and R₅₁, those resistors, R₄₂ and R₅₂, and those of the resistors, R₄₃ and R₅₃, are 2 kΩ and 6 kΩ, 4 kΩ and 4 kΩ, and 6 kΩ and 2 kΩ, respectively. Other parameters are same with those set in the v-ATT 100 of the first embodiment. That is, the first resistive divider comprised of the resistors, R₄₁ and R₅₁, has the dividing ratio of 2/8=¼, the second one has the dividing ratio of 4/8=½, and the third one has the dividing ratio of 6/8=¾, respectively.

Varying the control signal Vcont from −3 to 0 V, the gate biases for the FETs, 10 to 30, vary −0.75 to 0 V, −1.5 to 0 V, and −2.25 to 0 V, respectively. Thus, the v-ATT 100A of the second embodiment may configure the first and second stages of the FETs in the cascade connection concurrently with the gate biases supplied to the respective stages different from each other.

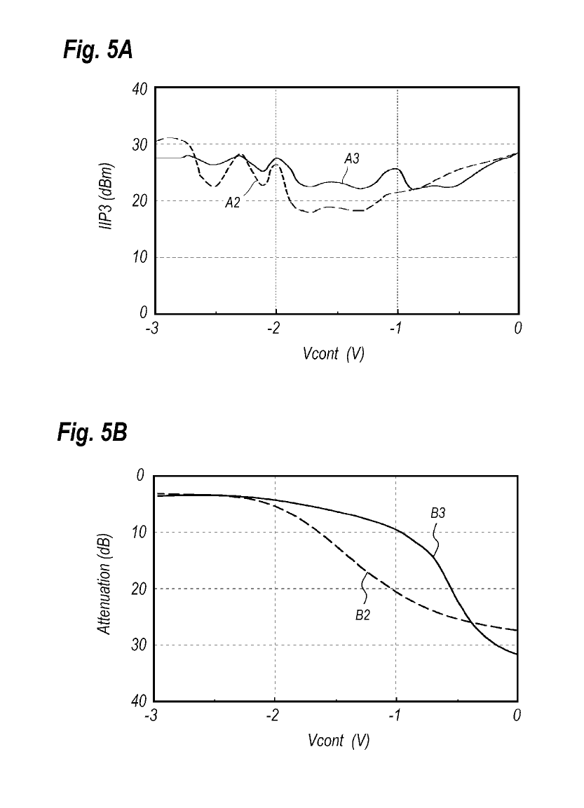

FIG. 5A and FIG. 5B compare the distortion performance measured through the IIP3 and the attenuation of the v-ATT 100A according to the second embodiment with the conventional v-ATT 200A shown in FIG. 11B that also provides the cascade connections in the first to third stages of the FETs. Referring to FIG. 5A, the v-ATT 100A of the present embodiment may show a behavior A3 of the IIP3 that enhances by about 4 dB in a range of the control signal Vcont from −2 to −1 V, which is greater than that secured by the first embodiment shown in FIG. 1 and FIG. 2B by about 10 dB. While, referring to FIG. 5B, the v-ATT 100A of the second embodiment secures the behavior B3 in the attenuation thereof greater than 30 dB at the control signal Vcont of 0 V, where all FETs, 10 to 30, 12, and 22, turn on, which is greater than that attained in the conventional v-ATT 200A by about 4 dB. Thus, the v-ATT 100A according to the second embodiment may make the distortion performance measured through the IIP3 consistent with the maximum attenuation.

The v-ATT 100A of the second embodiment provides the cascade connection of the FETs, 10 and 12, at least in the first stage that is arranged closest to the input terminal Tin. The first stage, which receives the signal with a greatest magnitude compared with the second and third stages, has the cascade connection; accordingly, the v-ATT 100A may improve the distortion performance, in particular, that measured through the IIP3.

Besides, the v-ATT 100A provides the last stage, which is arranged closest to the output terminal Tout, having the non-cascade connection. Because the last stage receives the signal attenuated by the upstream stages, the last stage becomes dull in the distortion performance. Accordingly, the FET 30 in the last stage has no cascade connection and large attenuation thereof may be secured. Thus, the first stage arranged closest to the input terminal preferably has the cascade connection from a viewpoint of the distortion performance, while, the stages except for the first stage are unnecessary to have the cascade connection.

The v-ATT 100A further has a feature that the stages receive the gate biases different from each other, which may shift the peak positions of the conductance, |ΔId|/|ΔVcont|, with respect to the control signal Vcont and the distortion performance measured through the IIP3 may be improved. The number of FETs including within a cascade connection is not restricted to two. Three or more FETs may be configured with the cascade connection. In particular, when the signal entering the input terminal Tin has extreme magnitude, three or more FETs are inevitable to be configured with the cascade connection in order to divide the power of the signal evenly into the respective FETs in a level lower than a breakdown level.

Also, the first and the second embodiments of the v-ATTs, 100 and 100A, provide three stages of the FETs. However, the v-ATT is necessary to provide at least two stages of the FETs. The v-ATTs, 100 and 100A, may have a configuration of, what is called, monolithic microwave integrated circuit (MMIC) formed on a unique semiconductor substrate. The v-ATTs, 100 and 100A, provide a unique control terminal Tcont into which the control signal Vcont is provided. However, the v-ATTs, 100 and 100A, may have a configuration that the FETs, 10 to 30, in the respective stages independently receive control signals from the outsides of the v-ATTs, 100 and 100A. The signal entering the input terminal Tin may have frequency components in a microwave band, sub-millimeter band, and/or millimeter band.

### Third Embodiment

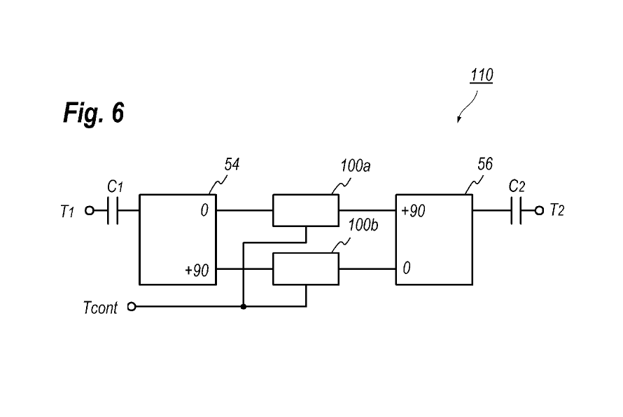

FIG. 6 shows a functional block diagram of an electronic apparatus according to the third embodiment of the present invention. The electronic apparatus 110 shown in FIG. 6 provides two v-ATTs, 100a and 100b, with a type of the first embodiment and/or the second embodiment, and two couplers, 54 and 56. Capacitors, C₁ and C₂, interposed between the input terminal T₁ and the first coupler 54, and between the second coupler 56 and the output terminal T₂, cut a DC component and low frequency components contained in the signal entering the input terminal T₁. The coupler 54 divides a signal coming from the input terminal T₁ into two portions having a phase difference of 90°, and provides thus divided two portions of the signal to the respective v-ATTs, 100a and 100b. The v-ATTs, 100a and 100b, attenuate the respective portions of the signal according to the control signal Vcont. The other coupler 56 mixes thus attenuated signals into one signal. Because the v-ATTs, 100a and 100b, causes no phase shift during the attenuation thereof, the coupler 56 may mix these two attenuated signals having a phase difference of 90° into one signal and provides thus mixed signal onto the output terminal T₂.

### Fourth Embodiment

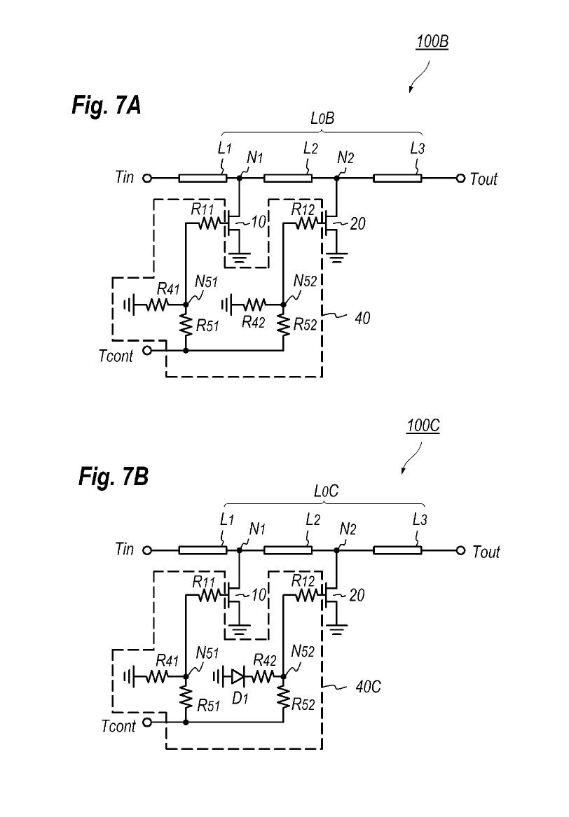

Another v-ATT according to the fourth embodiment in a circuit diagram thereof is shown in FIG. 7B, which is comparable to a v-ATT 100B shown in FIG. 7A and modified from the v-ATT 100 of the first embodiment shown in FIG. 1. Referring to FIG. 7A and FIG. 7B, the v-ATTs, 100B and 100C, provide three transmission elements, L₁ to L₃, and two stages of the FETs, 10 and 20, connected between the transmission line elements, L₁ to L₃, and the ground. Other arrangements of the v-ATTs, 100B and 100C, are same with those of the v-ATT 100 shown in FIG. 1. The v-ATT 100C according to the fourth embodiment provides a diode D1 in the bias unit 40C, where the diode D1 is connected between the ground and the common node N₅₂ of the T-network through the resistor R₄₂.

The attenuation of the v-ATTs, 100B and 100C, is evaluated. The diode D₁ in those embodiments has a type of high electron mobility transistor (HEMT) with a gate operable as an anode, while a source and a drain short-connected with the source operable as a cathode. The HEMT provides a carrier transporting layer, which is often called as a channel layer, made of gallium nitride (GaN); a carrier supplying layer, which is often called as a barrier layer, made of aluminum gallium nitride (AlGaN); and a gate length of 0.15 μm. The FETs, 10 to 30, implemented within the v-ATTs, 100B and 100C, have a gate width of 400 μm, while, that of the diode D₁ is set to be 150 μm. Resistance of the resistors, R₁₁ and R₁₂, R₄₁ and R₄₂, and R₅₁ and R₅₂, are set to be 3 kΩ and 3 kΩ, 10 kΩ and 10 kΩ, 6 kΩ and 0.2 kΩ, respectively, for the v-ATT 100B shown in FIG. 7A, which means that the dividing ratios of the first and the second resistive dividers in the T-networks become, 10/16 (=⅝) and 10/10.2 (˜1.0), respectively. That is, the FET 20 in the second stage receives the control signal Vcont without substantial splitting. For the v-ATT 100C shown in FIG. 7B, the resistor R52 in the second T-network is set in resistance thereof to be 6 kΩ; then the dividing ratio of the second T-network becomes substantially identical with that of the first T-network. The signal entering the input terminal Tin has a frequency of 14 GHz and power of 0 dBm. The control signal Vcont varies from −5 to 0 V.

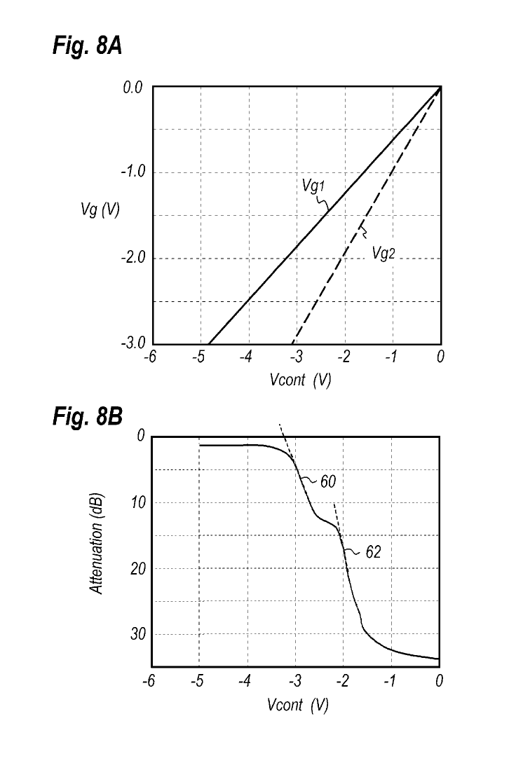

FIG. 8A and FIG. 8B show the gate biases and the attenuation of the v-ATT 100B modified from the first embodiment. In FIG. 8A, a behavior Vg₁ corresponds to the gate bias for the FET 10 in the first stage, while, another behavior Vg₂ corresponds to the gate bias for the FET 20 in the second stage. Because the FET 10 in the first stage receives the control signal Vcont divided by the first resistive divider in the first T-network whose dividing ratio is set to be ⅝, while, the FET 20 in the second stage receives the control signal Vcont divided by the second resistive divider in the second T-network whose dividing ratio is nearly 1.0, that is, the second FET 20 receives control signal Vcont without substantial division as the gate bias. On the other hand, the gate biases, Vg₁ and Vg₂, become 0 V when the control signal Vcont becomes 0 V. Thus, the relation between the gate bias Vg₁ and the control signal Vcont becomes moderate compared with the relation between the gate bias Vg₂ and the control signal Vcont.

When the control signal is low enough so as to fully turn off the FETs, 10 and 20, specifically lower than −4 V; the FETs, 10 and 20, turn off and the v-ATT 100B shows substantially no attenuation. Although FIG. 8B shows residual attenuation of about 3 dB; this residual attenuation is due to a leak through a parasitic capacitance between the current terminals of the FETs, 10 and 20. Further referring to FIG. 8B, the attenuation begins to increase from the control signal Vcont of about −3 V, which corresponds to a status where the first FET 10 begins to turn on and impedance between the current terminals thereof begins to decrease. The efficiency or a slope 60 of the control signal Vcont in the attenuation is estimated to be about 17 dB/V.

Further increasing the control signal Vcont, the attenuation begins to increase again from the control signal Vcont of −2 V. The efficiency or a slope 62 thereat reaches 37 dB/V, which is greater than twice of the former efficiency. The second increase in the attenuation is due to the strong relation between the gate bias Vg₂ for the FET 20 and the control signal Vcont.

Moreover, the attenuation in FIG. 8B shows a step between two efficiencies, 60 and 62. A step appearing in the attenuation in addition to a greater efficiency between the attenuation and the control signal Vcont makes the control of the attenuation by the control signal Vcont in the v-ATT 100B so sensitive and hard to secure a stable control. Setting the relation between the gate bias and the control signal Vcont in the respective FETs, 10 and 20 closer to each other in order to eliminate the step in the attenuation, such a v-ATT has the arrangement of the conventional v-ATT 200 shown in FIG. 11A. Accordingly, the consistency between the distortion performance and the attenuation is hard to be secured.

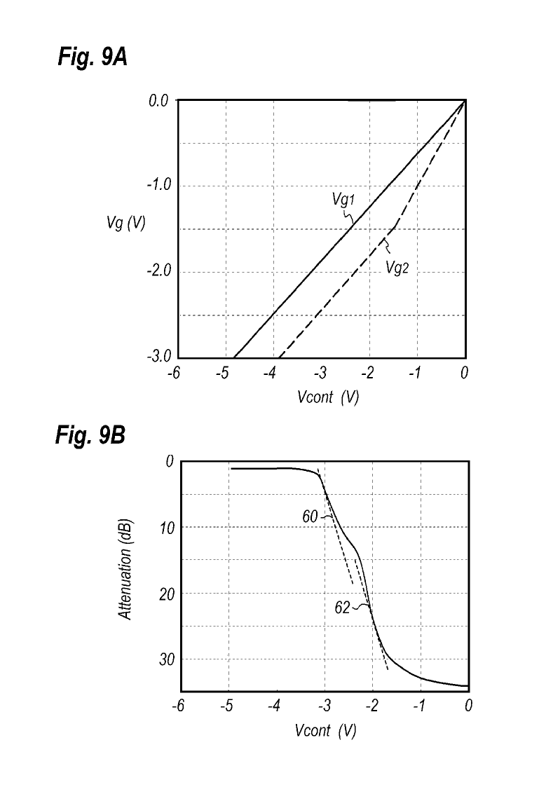

FIG. 9A and FIG. 9B show the gate biases, Vg₁ and Vg₂, for the FETs, 10 and 20, and the attenuation performance, each against the control signal Vcont, of the v-ATT 100C shown in FIG. 7B according to the fourth embodiment of the present invention. Referring to FIG. 9A, the slopes of the gate biases, Vg₁ and Vg₂, are substantially comparable to each other for the control signal below −1.5 V; because the dividing ratio in the resistive divider including the resistors, R₄₁ and R₅₁, in the resistance thereof are equal to those of the resistors, R₄₂ and R₅₂. Because of the existence of the diode D₁ in the second resistive divider in the second T-network, the biases, Vg₁ and Vg₂, show discrepancy for the control voltage Vcont in a region higher than −1.5 V where the diode D₁ gradually turns off and shows high impedance. Note that the diode D₁ of the present embodiment is a type of field effect transistor (FET) made of nitride semiconductor materials, where the gate thereof is operable as an anode, while, the source and the drain short-circuited with the source are operable as a cathode.

Referring to FIG. 9B, the v-ATT 100C shows the attenuation efficiency 60 of about 20 dB/V for the control signal Vcont of about −3 V. Also, the attenuation efficiency 62 becomes about 19 dB/V at the control signal Vcont of −2 V, which is comparable with the attenuation efficiency for the control signal Vcont at −3 V. Besides, the attenuation shows only a small step for the control signal Vcont from −3.2 to −1.5 V, which means that the attenuation of the v-ATT 100C may be stably controlled by the control signal Vcont.

### Modification of Fourth Embodiment

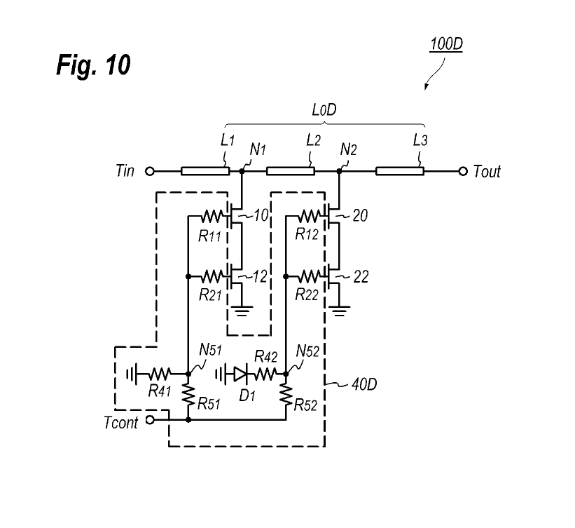

FIG. 10 shows a circuit diagram of a v-ATT 100D modified from the v-ATT 100C of the fourth embodiment. The v-ATT 100D provides the cascade connection in the first and the second stages of the FETs. Specifically, the first cascade connection of the FETs, 10 and 12, is provided between the node N₁ and the ground, while, the second cascade connection of the FETs, 20 and 22 is provided between the node N₂ and the ground. The first cascade connection of the FTEs, 10 and 12, receives the gate biases through the T-network comprised of the resistors, R₁₁, R₂₁, R₄₁, and R₅₁, while, the FETs, 20 and 22, receive the gate biases through the second T-network including the diode D₁ and the resistors, R₁₂, R₂₂, R₄₂, and R₅₂, where the resistors, R₂₁ and R₂₂, have resistance of 1 kΩ. Other configurations of the v-ATT 100D are same with those of the v-ATT 100C shown in FIG. 7B.

The bias units, 40C and 40D, provide the input terminal Tcont that receives the control signal Vcont, and the diode D₁ provided in the second resistive divider in the second T-network, specifically, the diode D₁ is provided between the ground in the anode thereof and the common node N₂ through the resistor R₄₂. Accordingly, a variation in the attenuation of the v-ATT 100D against a variation of the control signal Vcont may become moderate and may case no singularity.

In order to align the behavior of the gate bias Vg₁ against the control signal Vcont with that of the gate bias Vg₂; the dividing ratio of the first resistive divider in the first T-network, namely, the resistors, R₄₁ and R₅₁, are necessary to substantially align with the resistance ratio of the resistors, R₄₂ and R₅₂, in the second T-network.

The difference in the behaviors of the gate biases, Vg₁ and Vg₂, is determined by the forward saturation voltage of the diode D₁, which is about 1.0 V for the diode D₁ made of nitride semiconductor materials. Two or more diodes connected in series with the resistor R₄₂ may increase the difference in the gate biases, Vg₁ and Vg₂. When a diode made of other semiconductor materials, typically, silicon (Si), the difference between the gate biases, Vg₁ and Vg₂, may be 0.7 to 0.8V

The fourth embodiment provides two stages of the FETs, 10 and 12. However, a v-ATT may provide three or more stages of the FETs where the last stage closest to the output terminal Tout, or stages closer to the output terminal Tout may receive gate biases shifter by a diode in a T-network. Also, the electronic circuit 110 shown in FIG. 6 may implement the v-ATTs, 100₁ and 100₂, having the v-ATT 100D of the fourth embodiment.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

The present application claims the benefit of priority of Japanese Patent Applications No. 2017-032039, filed on Feb. 23, 2017, and No. 2017-157186 filed on Aug. 16, 2017, which are incorporated herein by references.

What is claimed is:

1. A variable attenuator, comprising:
an input terminal that receives a signal containing high frequency components;
an output terminal that outputs another signal attenuated from the signal received at the input terminal;
a transmission line that couples the input terminal with the output terminal, the transmission line;
a first stage connected between the transmission line and a ground, the first stage including a first field effect transistor (FET) having a gate, a current terminal connected with the transmission line, and another current terminal connected to the ground, the FET varying impedance between the current terminal and the another current terminal according to a first bias supplied to the gate;
a second stage connected between the transmission line and the ground, the second stage including a second FET having gate, a current terminal connected with the transmission line, and another current terminal connected to the ground, the second FET varying impedance between the current terminal and the another current terminal thereof according to a second bias supplied to the gate thereof;
a bias unit including an input, the bias unit generating the first bias and the second bias according to a control signal provided to the input of the bias unit, the bias unit supplying the first bias to the first stage and the second bias to the second stage,
wherein the first bias is different from and independent of the second bias.

2. The variable attenuator according to claim 1,
wherein the first bias has a range and a center of the range each different from a range and a center of the range of the second bias.

3. The variable attenuator according to claim 1,
further including another stage connected between the transmission line and the ground, the another stage including another FET having a gate, a current terminal connected with the transmission line, and another current terminal connected with the ground, the another FET varying impedance between the current terminal and the another current terminal of the another FET according to another bias supplied to the gate thereof,
wherein at least the first bias supplied to the first stage is different from the second bias and the another bias.

4. The variable attenuator according to claim 3,
wherein the first stage is arranged closest to the input terminal.

5. The variable attenuator according to claim 1,
wherein the first stage is arranged closer to the input terminal, and includes an additional FET, the first FET and the additional FET constituting a cascade connection between the transmission line and the ground, and
wherein the first FET and the additional FET receive the first bias in respective gates thereof.

6. The variable attenuator according to claim 5,
wherein the second stage is arranged closer to the output terminal and includes no additional FETs.

7. The variable attenuator according to claim 1,
wherein the bias unit includes a first resistive divider having a first dividing ratio and a second resistive divider having a second dividing ratio different from the first dividing ratio, the first bias being formed by the first resistive divider by dividing the control signal according to the first dividing ratio, the second bias being formed by the second resistive divider by dividing the control signal according to the second dividing ratio.

8. The variable attenuator according to claim 7,
wherein at least the first resistive divider includes a diode that shifts the first bias by a forward voltage of the diode.
